(19) United States
(12) Patent Application Publication
(10) Pub. No.: US 2013/0109134 A1
(43) Pub. Date: May 2, 2013

(54) METHOD OF MANUFACTURING SEMICONDUCTOR DEVICE

(71) Applicants: Susumu HATAKENAKA, Tokyo (JP); Zempei KAWAZU, Tokyo (JP); Hiroyuki KAWAHARA, Tokyo (JP); Takashi NAGIRA, Tokyo (JP)

(72) Inventors: Susumu HATAKENAKA, Tokyo (JP); Zempei KAWAZU, Tokyo (JP); Hiroyuki KAWAHARA, Tokyo (JP); Takashi NAGIRA, Tokyo (JP)

(73) Assignee: MITSUBISHI ELECTRIC CORPORATION, Tokyo (JP)

(21) Appl. No.: 13/535,434

(22) Filed: Jun. 28, 2012

(30) Foreign Application Priority Data
Oct. 27, 2011 (JP) 2011-235691

(51) Int. Cl. H01L 21/322

(52) U.S. Cl. 438/102; 257/E21.317

(57) ABSTRACT

A method of manufacturing a semiconductor device, includes introducing a substrate into a growth furnace, forming impurity absorption layers on the substrate and on inner walls of the growth furnace, the impurity absorption layers absorbing impurities on a surface of the substrate and impurities in the growth furnace, etching and removing the impurity absorption layers and a portion of the substrate to produce a thinned substrate, forming a buffer layer on the thinned substrate, and forming semiconductor layers on the buffer layer.

### BACKGROUND OF THE INVENTION

1. Field of the Invention

The present invention relates to a method of manufacturing semiconductor devices such as field effect transistors (FETs) and high electron mobility transistors (HEMTs) formed, e.g., of Group III-V compound semiconductor.

2. Background Art

Japanese Laid-Open Patent Publication No. 2003-243308 discloses a technique for forming a dummy layer on a multilayer structure. The dummy layer serves to getter or absorbs unwanted elements remaining in the growth furnace. The dummy layer is etched away after it has gettered unwanted elements.

The semiconductor device manufacturing method disclosed in the above publication is disadvantageous in that, since the dummy layer is formed on the multilayer structure after forming the structure on the substrate, the impurities which adhered to the substrate before the crystal growth cannot be removed.

### SUMMARY OF THE INVENTION

The present invention has been made to solve the foregoing problem. It is, therefore, an object of the present invention to provide a method of manufacturing a semiconductor device, which is capable of removing impurities which adhered to the substrate before the crystal growth, as well as removing impurities in the growth furnace.

The features and advantages of the present invention may be summarized as follows.

According to one aspect of the present invention, a method of manufacturing a semiconductor device, includes an introduction step of introducing a substrate into a growth furnace, an absorption layer forming step of forming impurity absorption layers on the substrate and on inner walls of the growth furnace, the impurity absorption layers absorbing impurities on a surface of the substrate and impurities in the growth furnace, an etching step of etching away the impurity absorption layers and a portion of the substrate to produce a thinned substrate, a buffer layer forming step of forming a buffer layer on the thinned substrate, and a semiconductor layer forming step of forming semiconductor layers on the buffer layer.

Other and further objects, features and advantages of the invention will appear more fully from the following description.

### BRIEF DESCRIPTION OF THE DRAWINGS

FIG. 1 is a flowchart showing a method of manufacturing a semiconductor device in accordance with a first embodiment of the present invention;

FIG. 2 is a diagram showing the growth furnace and the substrate after the substrate has been introduced into the growth furnace;

FIG. 3 is a diagram showing the impurity absorption layers after they have been formed;

FIG. 4 is a diagram showing the way in which the HCl gas is supplied to the growth furnace interior space in the etching step;

FIG. 5 is a diagram showing the growth furnace interior space after the completion of the etching step;

FIG. 6 is a diagram showing the buffer layer after it has been formed;

FIG. 7 is a diagram showing the HEMT structure and the HBT structure after they have been formed on the buffer layer;

FIG. 8 is a diagram showing getter members disposed around the substrate in accordance with the second embodiment;

FIG. 9 is a diagram showing the growth furnace and the substrate and the getter members disposed in the growth furnace;

FIG. 10 is a diagram showing the absorption layer forming step in accordance with the second embodiment;

FIG. 11 is a diagram showing the way in which the HCl gas is supplied to the growth furnace interior space;

FIG. 12 is a diagram showing the growth furnace interior space after the completion of the etching step;

FIG. 13 is a diagram showing the buffer layer after it has been formed; and

FIG. 14 is a diagram showing the HEMT structure and the HBT structure after they have been formed on the buffer layer.

### DETAILED DESCRIPTION OF THE PREFERRED EMBODIMENTS

### First Embodiment

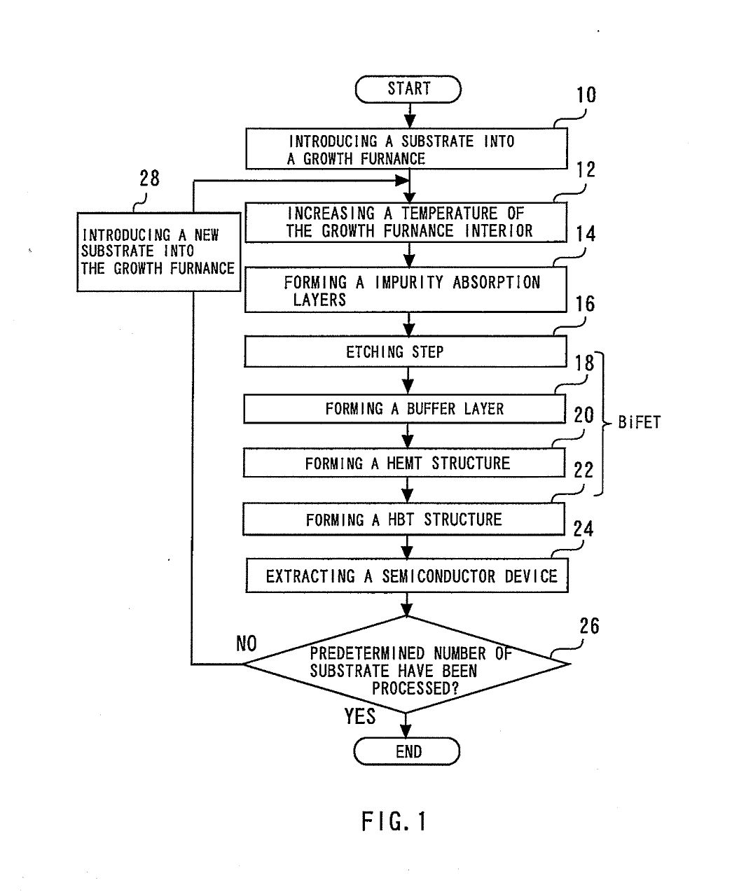

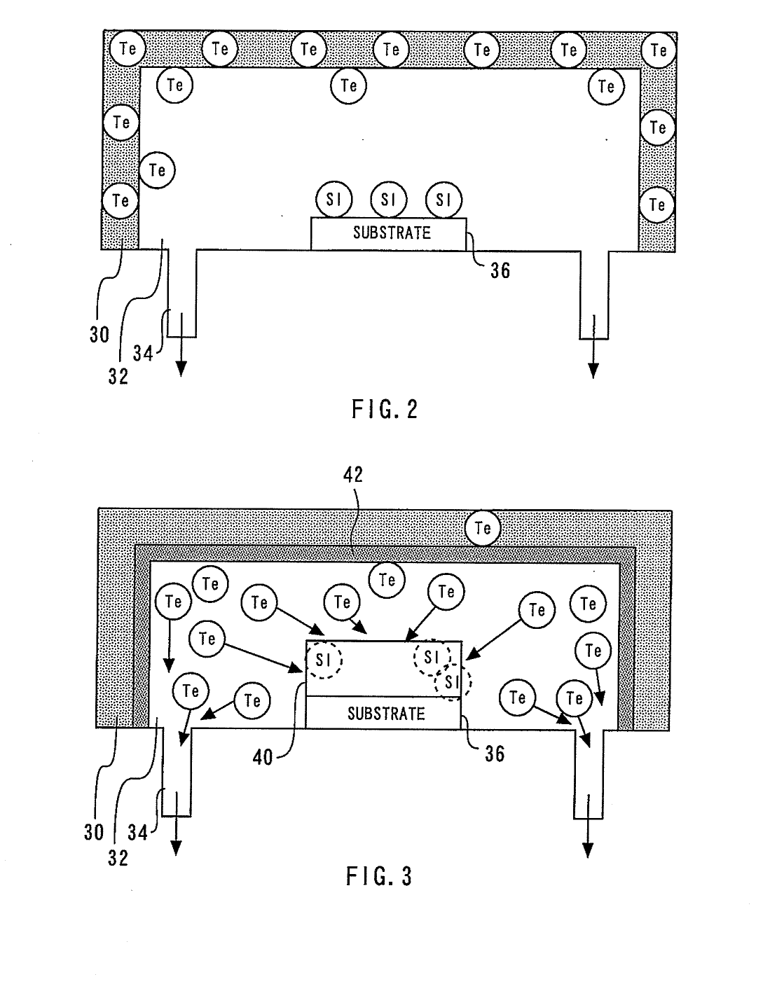

FIG. 1 is a flowchart showing a method of manufacturing a semiconductor device in accordance with a first embodiment of the present invention. The method of manufacturing a semiconductor device in accordance with the first embodiment will be described by following this flowchart and with reference at times to other drawings. First, a substrate is introduced into a growth furnace (step 10). This step is hereinafter referred to as the introduction step. FIG. 2 is a diagram showing the growth furnace and the substrate after the substrate has been introduced into the growth furnace. The growth furnace 30 is an MOCVD apparatus. Connection pipes 34 are coupled to the growth furnace 30 in order to evacuate the growth furnace interior space 32. The substrate 36 is formed of GaAs and is semi-insulating.

The growth furnace 30 has Te (tellurium) adhering thereto as a result of treatment performed in the growth furnace interior space 32 before the substrate 36 was introduced into the growth furnace 30. Further, the substrate 36 has Si adhering to its surface. The Te and Si, which are in this case unwanted elements, are referred to herein as “impurities.”

Next, the temperature of the growth furnace interior space 32 is increased to 600-700° C. (step 12). Impurity absorption layers are then formed on the substrate 36 and on the inner walls of the growth furnace 30 while maintaining the temperature of the growth furnace interior space 32 at a high temperature, namely, 600-700° C. (step 14). This step is hereinafter referred to as the absorption layer forming step. FIG. 3 is a diagram showing the impurity absorption layers after they have been formed. Specifically, an impurity absorption layer 40 is formed on the substrate 36, and an impurity absorption layer 42 is formed on the inner walls of the growth furnace 30, as shown in FIG. 3. These impurity absorption layers 40 and 42 serve to absorb impurities in the growth furnace interior space 32 and those on the surface of the substrate 36. The impurity absorption layers 40 and 42 are undoped Al_{0.50}Ga_{0.50}As layers grown by supplying TMGa, TMAl, and AsH₃ to the growth furnace interior space 32. The growth temperature is approximately 600-700° C., and the growth pressure is 60 mbar. The carrier gas may be hydrogen. The thickness of the impurity absorption layers 40 and 42 is approximately 500 nm.

Impurities, such as Te in the growth furnace interior space 32 and Si on the surface of the substrate 36, are gettered or absorbed by the impurity absorption layers 40 and 42 during the growth of these layers. After the completion of the absorption layer forming step, the supply of TMGa, TMAl, and AsH₃ to the growth furnace interior space 32 is stopped.

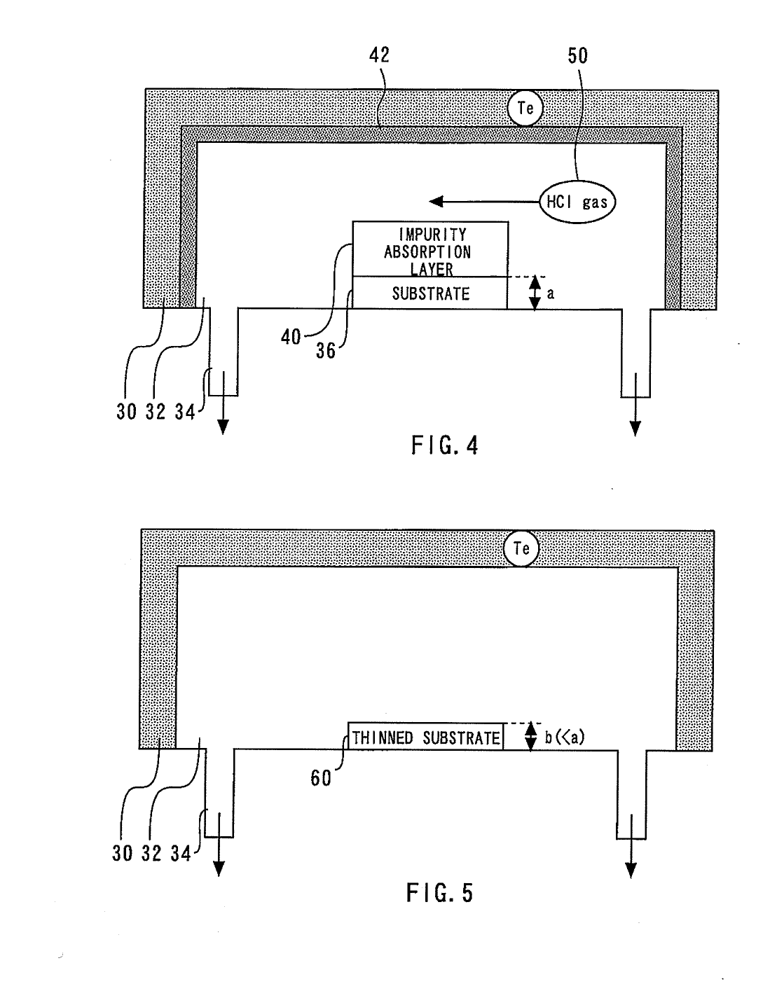

Next, the impurity absorption layers 40 and 42 and a portion of the substrate 36 are etched away (step 16). This step is hereinafter referred to as the etching step. In this etching step, HCl gas is supplied to the growth furnace interior space 32. FIG. 4 is a diagram showing the way in which the HCl gas is supplied to the growth furnace interior space in the etching step. The impurity absorption layers 40 and 42 and a portion of the substrate 36 are etched away by the HCl gas 50 supplied to the growth furnace interior space 32. Specifically, in the case of the substrate 36, approximately 1-2 μm of material is etched away from its surface. FIG. 5 is a diagram showing the growth furnace interior space after the completion of the etching step. The thickness of the substrate 36 before the etching step is denoted by the letter a in FIG. 4, while the thickness of the substrate 36 after the etching step is denoted by the letter b in FIG. 5 (i.e., b<a). The substrate 36 after it has been etched in the etching step is hereinafter referred to as the thinned substrate 60. It should be noted that the growth furnace interior space 32 is maintained at a high temperature (namely, 600-700° C.) until the completion of the etching step.

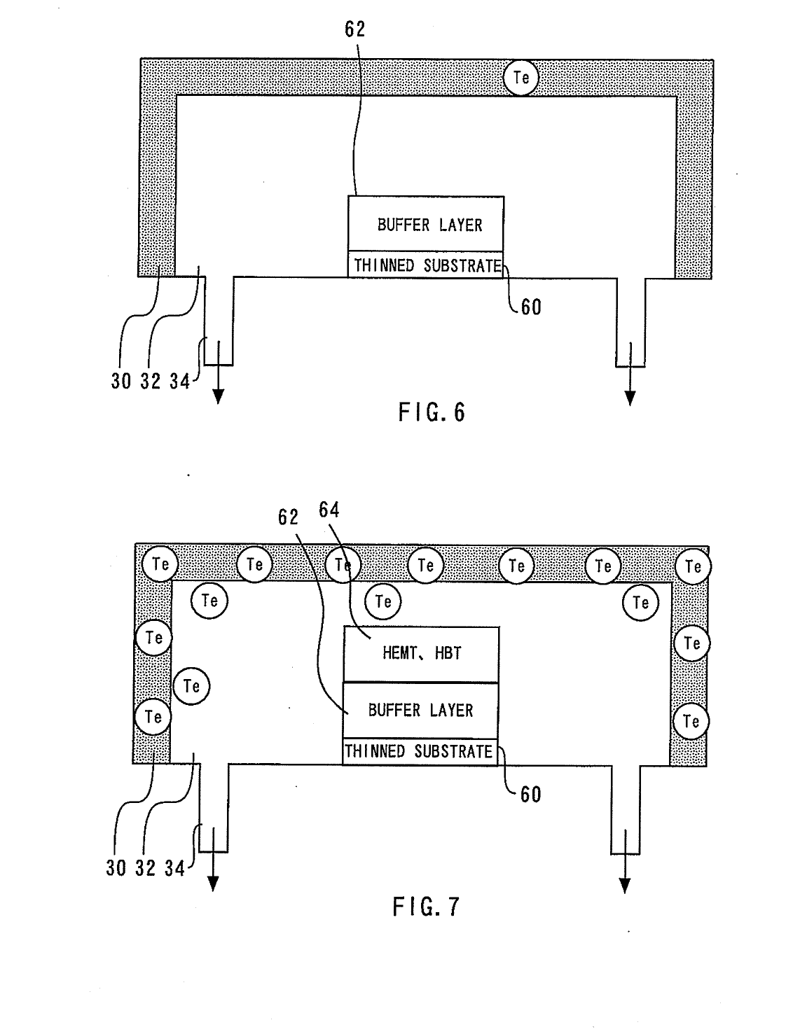

A buffer layer is then formed on the thinned substrate 60 (step 18) immediately after the etching step. This step is hereinafter referred to as the buffer layer forming step. FIG. 6 is a diagram showing the buffer layer after it has been formed. The buffer layer 62 is an undoped GaAs layer having a thickness of approximately 100 nm.

An HEMT structure is then formed on the buffer layer 62 (step 20). The HEMT structure includes a channel layer through which the source-drain current flows and an electron supply layer which supplies electrons to the channel layer, the channel layer and the electron supply layer being disposed on the buffer layer 62. Next, an HBT structure is formed on the HEMT structure (step 22). More specifically, epitaxial semiconductor layers are formed in steps 20 and 22. FIG. 7 is a diagram showing the HEMT structure and the HBT structure after they have been formed on the buffer layer. The combination of the HEMT and HBT structures formed on the buffer layer 62 is denoted by reference numeral 64 in FIG. 7. The buffer layer, the HEMT structure, and the HBT structure together form a so-called BiFET (bipolar field effect transistor) structure.

It should be noted that the top or final layer of the HBT structure formed in step 22 is a Te-doped In_{0.50}Ga_{0.50}As layer and is used as a contact layer. The formation of this final layer results in impurities, such as Te and Te-doped In_{0.50}Ga_{0.50}As, remaining in the growth furnace 30.

After the completion of the above step, the resulting completed semiconductor device is transferred out of the growth furnace 30 (step 24). Next, it is determined whether a predetermined number of substrates have been subjected to the above-described process steps (step 26). If the predetermined number of substrates have been subjected to the process steps, then the process is ended. If otherwise, then a new substrate is introduced into the growth furnace interior space 32 (step 28). The introduced new substrate is then subjected to step 12 and the subsequent steps.

It should be noted that in order to reduce the leakage current from the HEMT structure and maintain the electrical characteristics of the structure, it is necessary to increase the resistance of the buffer layer and thereby confine the current flowing through the channel layer of the HEMT structure so that the current does not leak from the channel layer to the outside. However, if the buffer layer is contaminated with impurities, it may not be possible to increase the resistance of the buffer layer. In accordance with the semiconductor device manufacturing method of the first embodiment, however, the impurity absorption layers 40 and 42 are formed so as to absorb impurities in the growth furnace interior space 32. Further, the impurity absorption layer 40 also absorbs impurities on the substrate 36, since the impurity absorption layer 40 is formed on the substrate 36. Therefore, the manufacturing method can be used to prevent the buffer layer 62 from being contaminated with impurities in the growth furnace interior space 32 and impurities which adhered to the substrate 36 before the crystal growth. Further, since the buffer layer 62 is formed immediately after the etching step, it is possible to minimize impurities present in the vicinity of the interface between the buffer layer 62 and the thinned substrate 60 so that the buffer layer 62 has a high resistance.

Since the substrate 36 is etched in the etching step, the surface of the resulting thinned substrate 60 is clean. As a result, it is possible to prevent impurities from entering the buffer layer 62 formed on the thinned substrate 60. It should be noted that the flatness of the surface of the thinned substrate 60 is poor, since the thinned substrate 60 is formed by etching the substrate 36. However, the surface of the buffer layer 62 formed on the thinned substrate 60 has a flatness comparable to that of the surface of the substrate 36 before the etching step.

In accordance with the semiconductor device manufacturing method of the first embodiment, since the buffer layer can be formed in an environment containing only a small amount of impurities, it is not necessary that the substrate be subjected to pretreatment or dummy growth in order to reduce impurities, making it possible to improve productivity in the manufacture of the semiconductor device and reduce its cost.

The impurity absorption layers 40 and 42 contain Al, which makes it possible to effectively getter or absorb impurities. However, the composition of the impurity absorption layers 40 and 42 is not limited to undoped Al_{0.50}Ga_{0.50}As. The only requirement for the composition of the impurity absorption layers is that they be formed of a Group III-V compound semiconductor composed of at least one Group III element selected from the group consisting of Al, Ga, and In, and at least one Group V element selected from the group consisting of N, P, and As. Examples of Group III source materials include trimethyl gallium (TMGa), trimethyl aluminum (TMAl), and trimethyl indium (TMIn), and examples of Group V source materials include arsine (AsH₃) and phosphine (PH₃). Examples of dopants include silane (SiH₄) and diisopropyl tellurium (DIPTe). It should be noted that the impurity absorption layers need not necessarily be lattice-matched to the substrate.

In the etching step, instead of HCl gas, other halogen compound gas may be used. Further, although in the above example an HEMT structure and an HBT structure are formed on the buffer layer, it is to be understood that any suitable device may be formed on the buffer layer in the semiconductor layer forming step while still achieving the advantages of the present embodiment. Suitable examples of impurities include, e.g., Se in addition to Te and Si. The required amount of etching of the substrate 36 in the etching step may be determined by taking the amount of impurities into account.

### Second Embodiment

A method of manufacturing a semiconductor device in accordance with a second embodiment of the present invention can reduce the impurities present in the growth furnace by an amount greater than that achievable by the semiconductor device manufacturing method of the first embodiment described above, although these methods follow the same basic process steps. The following description is directed to the semiconductor device manufacturing method of the second embodiment, but does not include features common to the first embodiment.

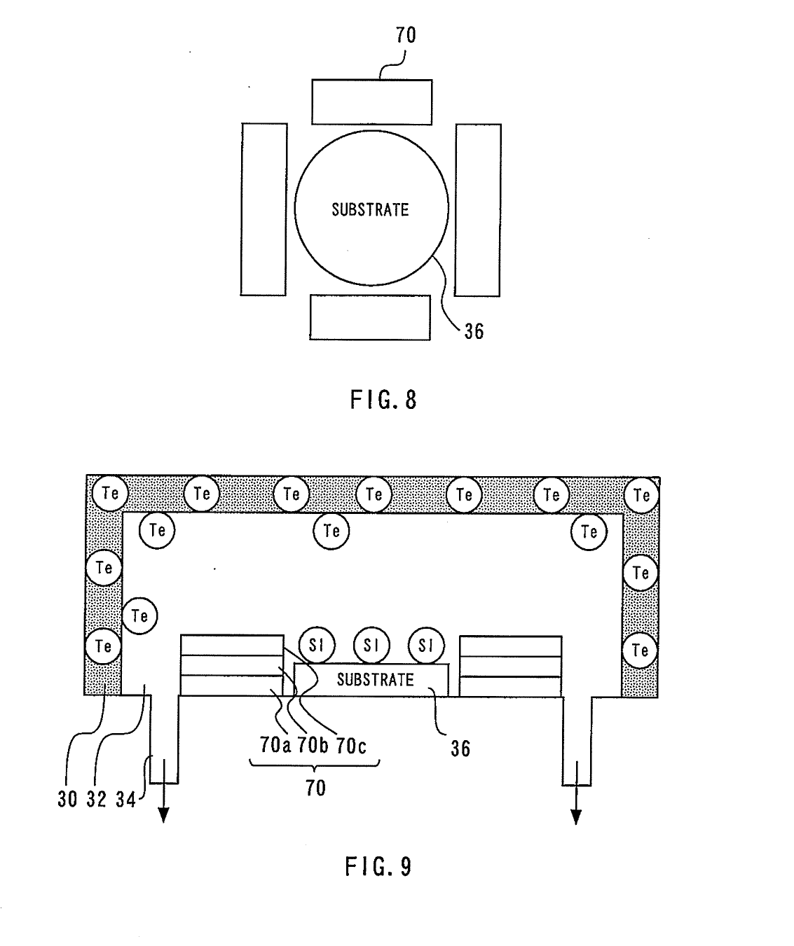

FIG. 8 is a diagram showing getter members disposed around the substrate in accordance with the second embodiment. Specifically, the getter members 70 are disposed around the substrate 36. The getter members 70 serve to absorb impurities. FIG. 9 is a diagram showing the growth furnace and the substrate and the getter members disposed in the growth furnace. Each getter member 70 includes a dummy substrate 70a. The dummy substrate 70a is formed of GaAs. A getter layer 70b is formed on the dummy substrate 70a. The getter layer 70b is formed of the same material as the impurity absorption layers formed in the absorption layer forming step, that is, the getter layer 70b is an undoped Al_{0.50}Ga_{0.50}As layer. A coating film 70c is formed on the getter layer 70b. The coating film 70c is an undoped GaAs film, which does not absorb impurities.

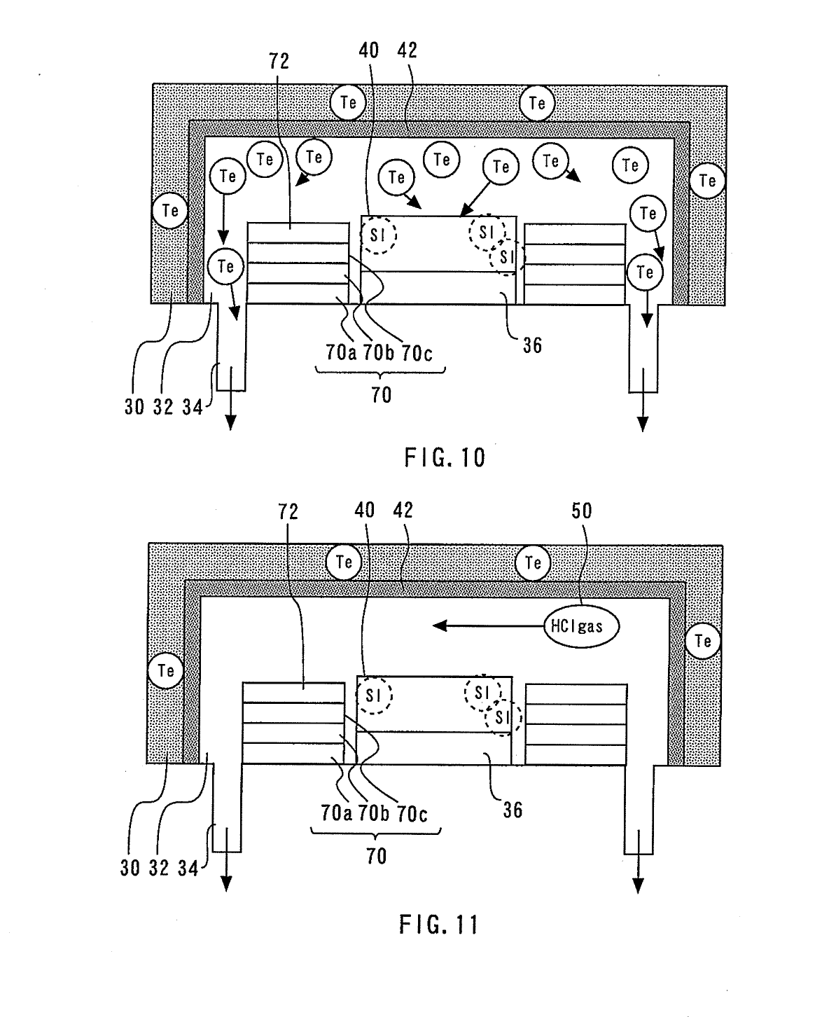

Next, the temperature of the growth furnace interior space 32 is increased to 600-700° C., and impurity absorption layers are formed. FIG. 10 is a diagram showing the absorption layer forming step in accordance with the second embodiment. In this absorption layer forming step, additional impurity absorption layers 72 which are of the same material as the impurity absorption layers 40 and 42 are formed on the getter members 70. The additional impurity absorption layers 72 are formed at the same time as the impurity absorption layer 40.

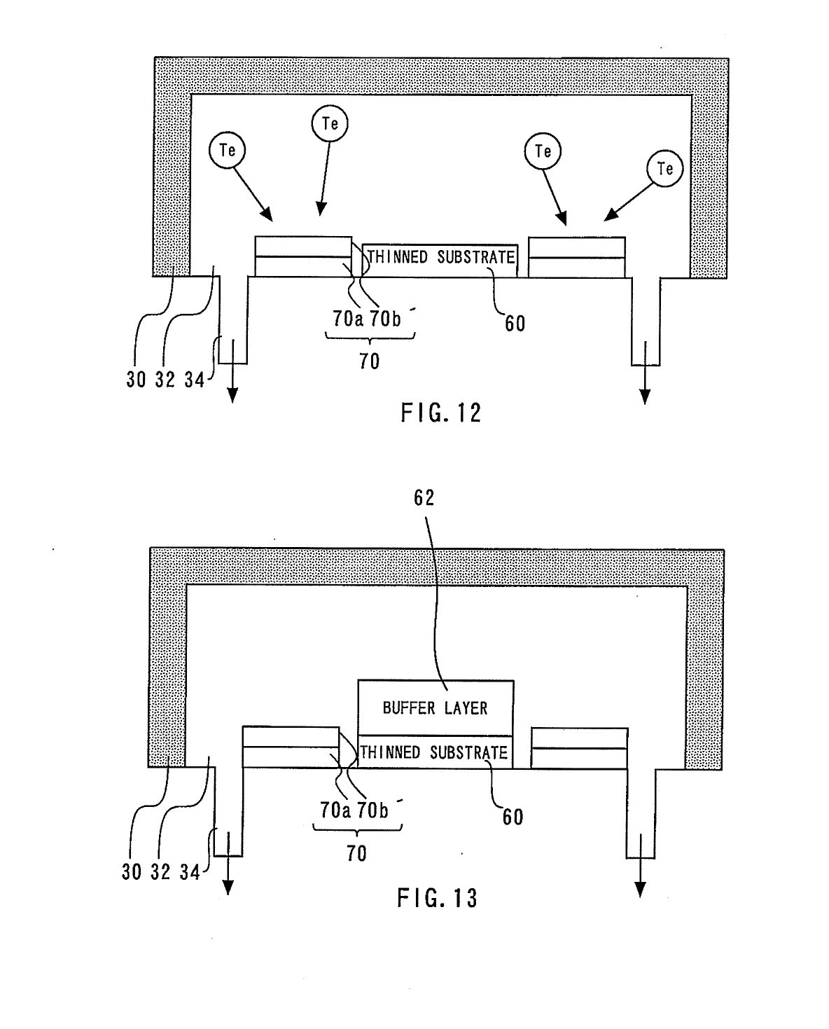

The process then proceeds to an etching step. In the etching step, HCl gas is supplied to the growth furnace interior space 32. FIG. 11 is a diagram showing the way in which the HCl gas is supplied to the growth furnace interior space. In this etching step, the additional impurity absorption layers 72, the coating films 70c, and a portion of the getter layers 70b are etched away. This etching is performed at the same time as when the impurity absorption layer 40 and a portion of the substrate 36 are etched away. FIG. 12 is a diagram showing the growth furnace interior space after the completion of the etching step. As a result of this etching step, the getter layers 70b of the getter members 70 are exposed and thinned. The resulting thinned getter layers are hereinafter referred to as the thinned getter layers 70b′. The temperature of the growth furnace interior space 32 is high (namely, 600-700° C.) immediately after the completion of the etching step, and a small amount of impurities remain therein. These impurities are gettered or absorbed by the thinned getter layers 70b′.

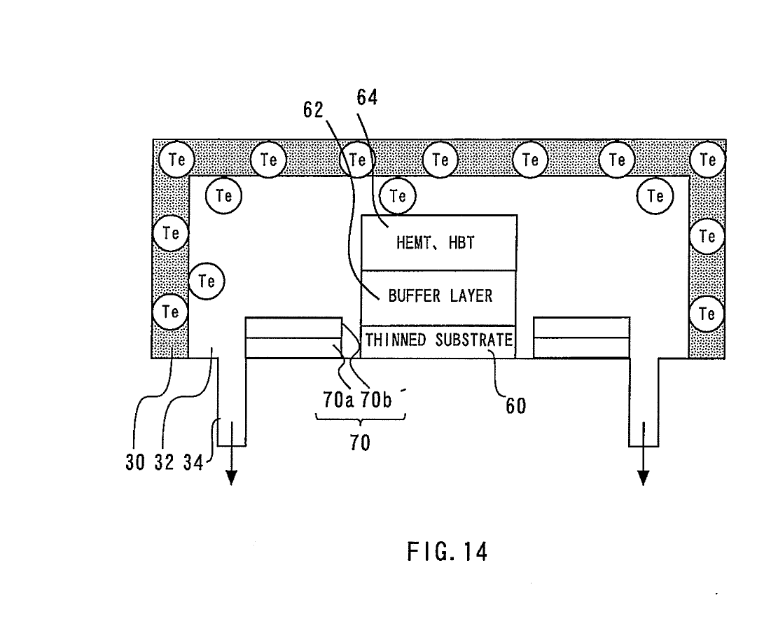

A buffer layer is then formed on the thinned substrate 60. FIG. 13 is a diagram showing the buffer layer after it has been formed. Next, an HEMT structure and then an HBT structure are formed. FIG. 14 is a diagram showing the HEMT structure and the HBT structure after they have been formed on the buffer layer. The resulting completed semiconductor device is then transferred out of the growth furnace, and a new substrate is introduced into the growth furnace interior space 32 as necessary.

In accordance with the semiconductor device manufacturing method of the second embodiment, the additional impurity absorption layer 72 is formed in addition to the impurity absorption layers 40 and 42, making it possible to effectively remove impurities in the absorption layer forming step. Since the temperature in the furnace is still high after the completion of the etching step, there is the possibility that impurities might adhere to the thinned substrate 60 during the period after the etching step is completed and before the buffer layer is grown. However, in the semiconductor device manufacturing method of the second embodiment, the small amount of impurities remaining in the furnace after the completion of the etching step are absorbed by the thinned getter layers 70b′, thereby maintaining the thinned substrate 60 clean.

It should be noted that the coating films 70c, which do not absorb impurities, have the following function. Since the getter layers 70b are covered with the coating films 70c until the completion of the etching step, the getter layers 70b do not absorb impurities until then. As a result of the etching step, the coating films 70c are removed, and the getter layers 70b are exposed and thinned. The resulting thinned getter layers 70b′ then begin to absorb impurities. Therefore, the thinned getter layers 70b′ retain significant ability to absorb impurities during the period after the completion of the etching step and before the formation of the buffer layer 62. As a result, the thinned getter layers 70b′ can fully absorb the small amount of impurities described with reference to FIG. 12, thereby preventing impurities from attaching to the thinned substrate 60. Thus, the coating films 70c are used to preserve the function of the getter layers 70b until the completion of the etching step.

The coating films 70c are not limited to specific material, but may be made of any suitable material which does not absorb impurities. Further, the coating layers 70c may be omitted from the getter members. The only requirement for the getter members 70 is that they have a getter layer formed on a dummy substrate so as to absorb impurities within the growth furnace. It should be noted that the semiconductor device manufacturing method of the second embodiment is susceptible of alterations at least similar to those that can be made to the semiconductor device manufacturing method of the first embodiment.

In accordance with the present invention, an impurity absorption layer is formed on a substrate so as to absorb impurities adhering to the substrate and impurities present in the growth furnace, making it possible to manufacture semiconductor devices having the desired performance characteristics by eliminating the effect of impurities in the semiconductor devices.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2011-235691, filed on Oct. 27, 2011, including specification, claims, drawings, and summary, on which the Convention priority of the present application is based, is incorporated herein by reference in its entirety.

1. A method of manufacturing a semiconductor device, comprising:
introducing a substrate into a growth furnace;
forming impurity absorption layers on said substrate and on inner walls of said growth furnace, said impurity absorption layers absorbing impurities on a surface of said substrate and impurities in said growth furnace;
etching and removing said impurity absorption layers and a portion of said substrate to produce a thinned substrate;
forming a buffer layer on said thinned substrate; and
forming semiconductor layers on said buffer layer.

2. The method according to claim 1, wherein said impurity absorption layers include a Group III-V compound semiconductor composed of at least one Group III element selected from the group consisting of Al, Ga, and In, and at least one Group V element selected from the group consisting of N, P, and As.

3. The method according to claim 1, including etching with a gaseous halogen compound.

4. The method according to claim 1, wherein:
forming said absorption layers includes forming an additional impurity absorption layer on a getter member, wherein
said getter member has a getter layer on a dummy substrate,
said getter layer absorbs said impurities in said growth furnace, and
said additional impurity absorption layer is the same material as said impurity absorption layers; and
etching includes etching and removing said additional impurity absorption layer and a portion of said getter layer.

5. The method according to claim 4, wherein said getter layer is the same material as said impurity absorption layers.

6. The method according to claim 4, including:
forming a coating film, which does not absorb the impurities in said growth furnace, on a surface of said getter member; and
removing said coating film in said etching.

7. The method according to claim 1, including forming, as the last layer formed in forming said semiconductor layers, a layer containing Te.

8. The method according to claim 1, including forming one of an HEMT and an HBT in forming said semiconductor layers.
